(19) United States
(12) Patent Application Publication
(10) Pub. No.: US 2005/0263848 A1
(43) Pub. Date: Dec. 1, 2005

(54) Metal-insulator-metal capacitor having a large capacitance and method of manufacturing the same

(76) Inventor: Kwang-lae Cho, Seongnam-si (KR)

Correspondence Address: LEE, STERBA & MORSE, P.C., SUITE 2000, 1101 WILSON BOULEVARD, ARLINGTON, VA, 22209, US

(21) Appl. No.: 11/097,165

(22) Filed: Apr. 4, 2005

(30) Foreign Application Priority Data
May 28, 2004 (KR) 04-38174

(51) Int. Cl. H01L 29/00; H01L 21/00

(52) U.S. Cl. 257/532; 438/396; 438/399

(57) ABSTRACT

A metal-insulator-metal (MIM) capacitor having a large capacitance, and a method of manufacturing the same, includes forming a lower electrode on a semiconductor substrate, sequentially forming a first dielectric film, an intermediary electrode, and a second dielectric film on an upper surface of the lower electrode, forming an inter-metal insulating layer on an upper surface of the second dielectric film, etching predetermined portions of the inter-metal insulating layer to form an upper electrode region and via hole regions, selectively etching the second dielectric film exposed in a portion of the via hole regions to expose the intermediary electrode, and forming a metal layer on the upper electrode region and the via hole regions, thereby forming an upper electrode and contact plugs.

### BACKGROUND OF THE INVENTION

1. Field of the Invention

The present invention relates to a Metal-Insulator-Metal (MIM) capacitor and a method of manufacturing the same. More particularly, the present invention relates to an analog MIM capacitor having a large capacitance and a method of manufacturing the same.

2. Description of the Related Art

As semiconductor integrated circuits become more diversely used, an analog capacitor formed in a logic circuit area is required to attain a high speed and a large capacitance. A high-speed capacitor may be achieved by lowering a resistance of a capacitor electrode to decrease reliance on frequency. A large-capacitance capacitor may be achieved by decreasing a thickness of a capacitor dielectric film, using a dielectric film with a high dielectric constant, or increasing a capacitor area.

In such an analog capacitor, an electrode is generally formed of a polysilicon layer. The polysilicon layer, however, has a large resistance and is easily oxidized, which impedes fabrication of a high-speed capacitor having a large capacitance.

To solve these problems, a technique using a metal layer as a capacitor electrode (hereinafter referred to as “MIM capacitor technique”) has been proposed. In this technique, because an electrode is formed using a metal layer having a sheet resistance lower than that of polysilicon, the MIM capacitor has high-speed characteristics. Moreover, use of a metal electrode results in no parasitic capacitance caused by inner depletion of the capacitor, so that the large capacitance can be achieved.

FIGS. 1 through 3 illustrate sectional views of stages in a conventional method of manufacturing a conventional MIM capacitor. As shown in FIG. 1, an interlayer insulating layer 20 is formed on a semiconductor substrate 10 on which devices (not shown) are formed. A lower electrode 30 and a metal interconnect 35 are formed in predetermined areas within the interlayer insulating layer 20. A dielectric film 40 and a metal layer 45 for an upper electrode are sequentially formed on an upper surface of the interlayer insulating layer 20, in which the lower electrode 30 and the metal interconnect 35 are formed.

Referring to FIG. 2, a predetermined portion of the metal layer 45 is etched to define an upper electrode 45a. A capping layer 50 is then deposited to cover the upper electrode 45a and the dielectric film 40.

Referring to FIG. 3, an inter-metal insulating layer 60 is deposited on an upper surface of the capping layer 50. Predetermined portions of the inter-metal insulating layer 60 are etched to expose the upper electrode 45a and the metal interconnect 35, thereby forming via holes 65. The via hole 65 is formed by well-known photolithography and etching.

In order to provide an adequate contact margin, entrances of the via holes 65 are enlarged. The entrances of the via holes 65 are also enlarged by well-known photolithography and etching.

The via holes 65 are then filled with a metal layer to form first and second contact plugs 70a and 70b. The first contact plug 70a is a medium for transferring electrical signals to the upper electrode 45a. The second contact plug 70b is a medium for electrically connecting the metal interconnect 35 to an upper metal interconnect (not shown).

However, the above-described MIM capacitor is limited in how much a thickness of the dielectric film may be reduced due to a high possibility of causing a leakage current. Therefore, an increase in the capacitance of the above conventional MIM capacitor is restricted. Although a capacitor area can be increased by another method of increasing the capacitance of the MIM capacitor, the above conventional MIM capacitor is also limited in increasing the capacitor area in view of the trend toward integrating the devices.

### SUMMARY OF THE INVENTION

The present invention is therefore directed to an analog MIM capacitor and a method of manufacturing the same, which substantially overcome one or more of the problems due to the limitations and disadvantages of the related art.

It is a feature of an embodiment of the present invention to provide a MIM capacitor that is capable of having a large capacitance and preventing a leakage current.

It is another feature of an embodiment of the present invention to provide a MIM capacitor including at least one capacitor connected in parallel, thereby increasing a capacitance of the MIM capacitor.

It is still another feature of an embodiment of the present invention to provide a MIM capacitor that is able to increase a capacitance of the capacitor without reducing a thickness of a dielectric film of the capacitor, thereby improving prevention of leakage current.

It is yet another feature of an embodiment of the present invention to provide a method of manufacturing a MIM capacitor that requires no additional photolithography processing.

According to an aspect of the present invention, there is provided a method of manufacturing a metal-insulator-metal (MIM) capacitor including forming a lower electrode on a semiconductor substrate, sequentially forming a first dielectric film, an intermediary electrode, and a second dielectric film on an upper surface of the lower electrode, forming an inter-metal insulating layer on an upper surface of the second dielectric film, etching predetermined portions of the inter-metal insulating layer to form an upper electrode region and via hole regions, selectively etching the second dielectric film exposed in a portion of the via hole regions to expose the intermediary electrode, and forming a metal layer on the upper electrode region and the via hole regions, thereby forming an upper electrode and contact plugs.

Forming the lower electrode may include forming an interlayer insulating layer on the semiconductor substrate and forming the lower electrode within the interlayer insulating layer, wherein a surface of the lower electrode is externally exposed.

The lower electrode may be composed of copper (Cu), aluminum (Al) or tungsten (W).

Sequentially forming the first dielectric film, the intermediary electrode and the second dielectric film may include sequentially stacking the first dielectric film, a metal layer, and the second dielectric film on an upper surface of the interlayer insulating layer and patterning the second dielectric film and the metal layer, each of the patterned second dielectric film and metal layer having a length longer than the lower electrode by as much as a predetermined length, the patterned second dielectric film and metal layer overlapping the lower electrode.

The method may further include enlarging entrances of the via holes by as much as a predetermined width while etching the second dielectric film in the portion of the via hole regions. Etching the second dielectric film on the via hole regions may include forming a photoresist pattern exposing the inter-metal insulating layer on both sides of the via holes, etching an upper region of the exposed inter-metal insulating layer to a predetermined depth, and etching the exposed second dielectric film.

According to another aspect of the present invention, there is provided a method of manufacturing a MIM capacitor including forming an interlayer insulating layer on an upper surface of a semiconductor substrate, the interlayer insulating layer having a lower electrode and a metal interconnect, sequentially depositing a first dielectric film, a metal layer for an intermediary electrode, a second dielectric film, and a passivation layer on an upper portion of the interlayer insulating layer, etching predetermined portions of the passivation layer, the second dielectric film, and the metal layer for the intermediary electrode, the etched passivation layer, second dielectric film, and metal layer overlapping the lower electrode, forming a capping layer on the passivation layer and the first dielectric film, forming an inter-metal insulating layer on an upper surface of the capping layer, the inter-metal insulating layer including a first insulating layer, an etch stopper, and a second insulating layer, etching a predetermined portion of the inter-metal insulating layer to form a preliminary upper electrode region, a first preliminary via hole and a second preliminary via hole, enlarging entrances of the first and second preliminary via holes, selectively etching the capping layer, the passivation layer, the second dielectric film and the first dielectric film to expose the second dielectric film in the preliminary upper electrode region, to expose the intermediary electrode in the first preliminary via hole, and to expose the metal interconnect in the second preliminary via hole, thereby defining an upper electrode region, a first via hole and a second via hole, respectively, and forming a metal layer on the upper electrode region and the first and second via holes, thereby forming an upper electrode and first and second contact plugs.

Forming the interlayer insulating layer having the lower electrode and the metal interconnect may include depositing the interlayer insulating layer on an upper portion of the semiconductor substrate, etching predetermined portions of the interlayer insulating layer to a predetermined depth to form first and second grooves, depositing a metal layer filling the first and second grooves, and planarizing the metal layer to expose the interlayer insulating layer, thereby forming the lower electrode and the metal interconnect.

The metal layer for forming the lower electrode and the metal interconnect may be composed of copper (Cu), aluminum (Al) or tungsten (W). The first and second dielectric films may be composed of a silicon nitride layer. The metal layer for the intermediary electrode may be composed of a titanium nitride (TiN) layer or tantalum nitride (TaN) layer. The passivation layer may be composed of a silicon oxide layer. The capping layer may be composed of a silicon nitride layer.

Etching the passivation layer, the second dielectric film and the metal layer for the intermediary electrode may include etching portions of the passivation layer, the second dielectric film and the metal layer, wherein the etched passivation layer, second dielectric film and metal layer overlap the lower electrode and a predetermined portion of the metal layer for the intermediary electrode extends beyond the lower electrode.

Forming the preliminary upper electrode region and the first and second preliminary via hole regions may include forming a first photoresist pattern to expose an area including the lower electrode on the inter-metal insulating layer, an area including the intermediary electrode extending beyond the lower electrode, and an area including the metal interconnect, etching the inter-metal insulating layer in the form of the first photoresist pattern to expose the capping layer, and removing the first photoresist pattern.

Enlarging the entrances of the first and second preliminary via holes may include forming a second photoresist pattern on both sides of the first and second preliminary via holes, the second photoresist pattern exposing predetermined portions of the inter-metal insulating layer and covering the preliminary upper electrode region, etching the second insulating layer of the inter-metal insulating layer in the form of the second photoresist pattern, removing the second photoresist pattern, and etching the exposed capping layer and the passivation layer using the etch stopper as a mask.

Forming the upper electrode and the contact plugs may include forming a metal layer filling the upper electrode region and planarizing the metal layer to expose a surface of the inter-metal insulating layer. Alternatively, forming the upper electrode and the contact plugs may include forming a metal layer filling the first and second via holes and planarizing the metal layer to expose a surface of the inter-metal insulating layer.

According to still another aspect of the present invention, there is provided a MIM capacitor including a semiconductor substrate, an interlayer insulating layer on an upper surface of the semiconductor substrate, the interlayer insulating layer including a lower electrode and a metal interconnect, a first dielectric film formed on the interlayer insulating layer, an intermediary electrode formed on the first dielectric layer and overlapping the lower electrode, a second dielectric film formed on an upper surface of the intermediary electrode, an upper electrode formed on an upper surface of the second dielectric film, and a first contact plug on the intermediary electrode for transferring signals to the intermediary electrode.

The MIM capacitor may further include a second contact plug on the metal interconnect.

The lower electrode and the metal interconnect may be buried in an upper portion of the interlayer insulating layer and surfaces of the lower electrode and the metal interconnect may be exposed.

A first portion of the intermediary electrode may overlap the lower electrode and a second portion of the intermediary electrode may extend beyond the lower electrode, and wherein the first contact plug may be formed on the second portion of the intermediary electrode extending beyond the lower electrode.

The MIM capacitor may further include an inter-metal insulating layer on an upper surface of the second dielectric film, wherein the upper electrode and the first contact plug are formed within the inter-metal insulating layer. The upper electrode may be buried in a predetermined portion of the inter-metal insulating layer. Alternatively, the upper electrode may have a cylindrical-shape and may be formed within the inter-metal insulating layer.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1 through 3 illustrate sectional views of stages in a conventional method of manufacturing a conventional MIM capacitor;

FIGS. 4 through 10 illustrate sectional views of stages in a method of manufacturing a MIM capacitor according to an embodiment of the present invention;

FIG. 11 illustrates a sectional view of a MIM capacitor according to an alternative embodiment of the present invention; and

FIG. 12 illustrates an equivalent circuit diagram of a MIM capacitor according to the present invention.

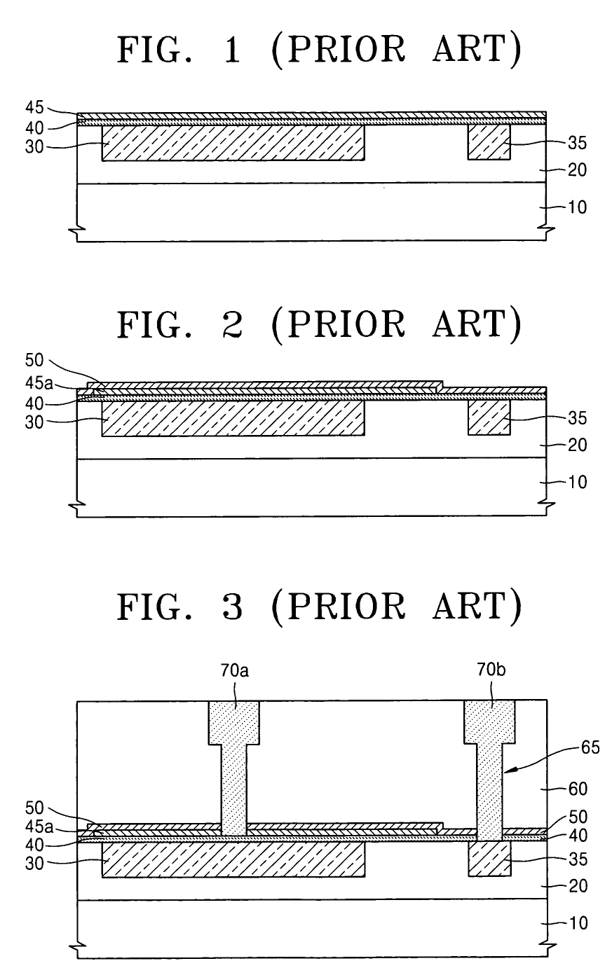

### DETAILED DESCRIPTION OF THE INVENTION

Korean Patent Application No. 2004-38174, filed on May 28, 2004, in the Korean Intellectual Property Office, and entitled: “Metal-Insulator-Metal Capacitor With High Capacitance and Method of Manufacturing the Same,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of films, layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

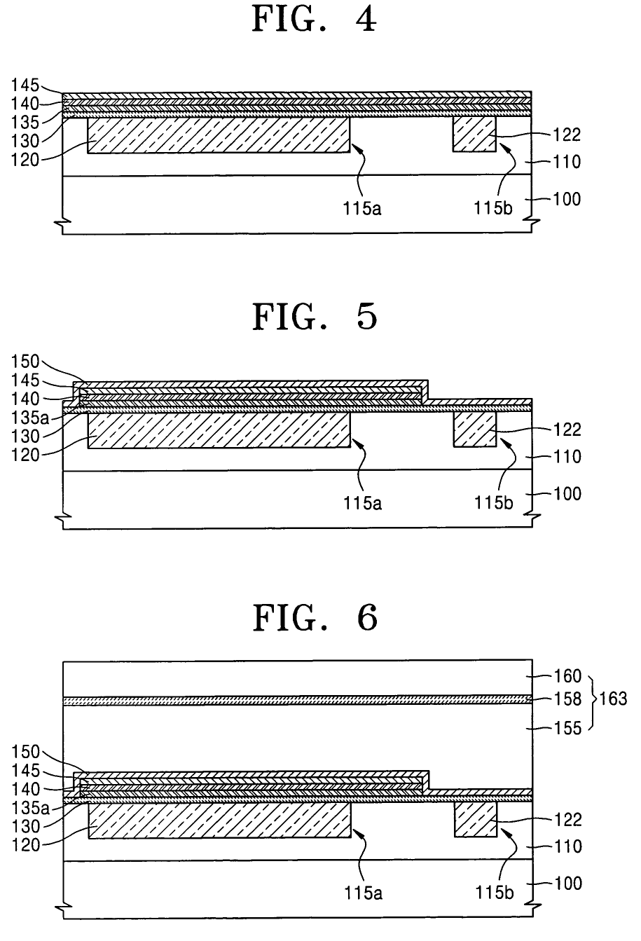

FIGS. 4 through 10 illustrate sectional views of stages in a method of manufacturing a MIM capacitor according to an embodiment of the present invention.

Referring to FIG. 4, an interlayer insulating layer 110 is deposited on an upper surface of a semiconductor substrate 100. Although not illustrated, devices, such as MOS transistors, are formed between the semiconductor substrate 100 and the interlayer insulating layer 110. Predetermined portions of the interlayer insulating layer 110 are etched to a predetermined depth, thereby forming first and second grooves 115a and 115b. A lower electrode 120 of a capacitor will be formed in the first groove 115a, and a metal interconnect 122 will be formed in the second groove 115b. A first metal layer is formed on an upper surface of the interlayer insulating layer 110 to fill the first and second grooves 115a and 115b. The metal layer may be composed of copper (Cu), aluminium (Al) or tungsten (W). Then, the first metal layer is planarized, e.g., using chemical mechanical polishing (CMP), to expose an upper surface of the interlayer insulating layer 110, thereby forming the lower electrode 120 and the metal interconnect 122. A first dielectric film 130, a second metal layer 135, a second dielectric film 140 and a passivation layer 145 are then sequentially stacked on an upper surface of the interlayer insulating layer 110, in which the lower electrode 120 and the metal interconnect 122 are formed. The first and second dielectric films 130 and 140 may be composed of, e.g., a silicon nitride layer (SiN) and may have a thickness of about 500-1000 Å for preventing a leakage current of a capacitor. The second metal layer 135 may be formed of an easily etched metal layer, such as a titanium nitride (TiN) or tantalum nitride (TaN) layer. The passivation layer 145 protects the second dielectric film 140 and may be formed of, e.g., a silicon oxide layer.

Referring to FIG. 5, the passivation layer 145, the second dielectric film 140, and the second metal layer 135 are etched to overlap the lower electrode 120, the etched second metal layer 135 defining an intermediary electrode 135a. Preferably, the intermediary electrode 135a has a greater length than the lower electrode 120 to extend beyond the lower electrode 120 by as much as a predetermined length. A capping layer 150 is then formed on an upper surface of a resultant structure of the semiconductor substrate 100. The capping layer 150 may be composed of, e.g., a silicon nitride layer, which blocks external diffusion of the lower electrode material, such as copper (Cu), and acts as an etch stopper when via holes are formed later.

Referring to FIG. 6, an inter-metal insulating layer 163, including sequentially a first insulating layer 155, an etch stopper 158, and a second insulating layer 160, is formed on an upper surface of the capping layer 150. The first and second insulating layers 155 and 160 may be formed of, e.g., a silicon oxide layer, and the etch stopper 158 may be a silicon nitride layer.

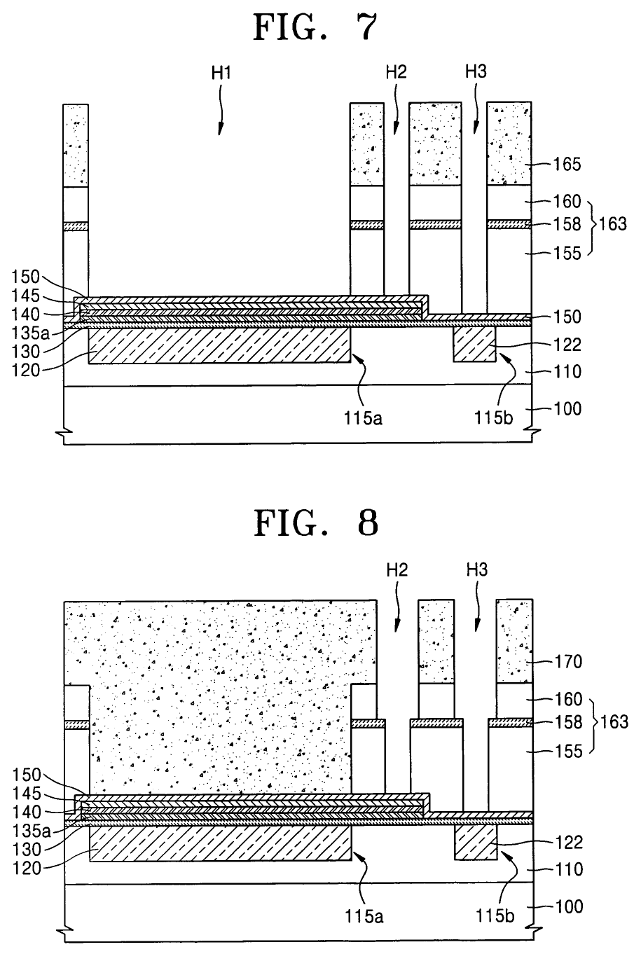

Referring to FIG. 7, in order to define via holes that connect an upper electrode region and metal interconnects of a capacitor, a first photoresist pattern 165 is formed on an upper surface of the second insulating layer 160 using photolithography. Using the first photoresist pattern 165 as a mask, the second insulating layer 160, the etch stopper 158, and the first insulating layer 155 are etched to expose the capping layer 150. As a result of this etching, a preliminary upper electrode region H1 and first and second preliminary via holes H2 and H3 are formed in the inter-metal insulating layer 163. A process for defining the preliminary upper electrode region H1 may correspond to a process of forming conventional preliminary via holes having enlarged entrances.

Referring to FIG. 8, the first photoresist pattern 165 is removed. Then, in order to enlarge entrances of the first and second preliminary via holes H2 and H3, a second photoresist pattern 170 is formed on both sides of the first and second preliminary via holes H2 and H3 to expose the first and second preliminary via holes H2 and H3 and the second insulating layer 160. At this time, the second photoresist pattern 170 may fill the preliminary upper electrode region H1. The second insulating layer 160 is etched in the form of the second photoresist pattern 170, thereby enlarging the entrances of the first and second preliminary via holes H2 and H3. At this time, because the inter-metal insulating layer 163 is formed of the first insulating layer 155, the etch stopper 158, and the second insulating layer 160, the entrances of the first and second preliminary via holes H2 and H3 can be enlarged by selectively etching only the second insulating layer 160.

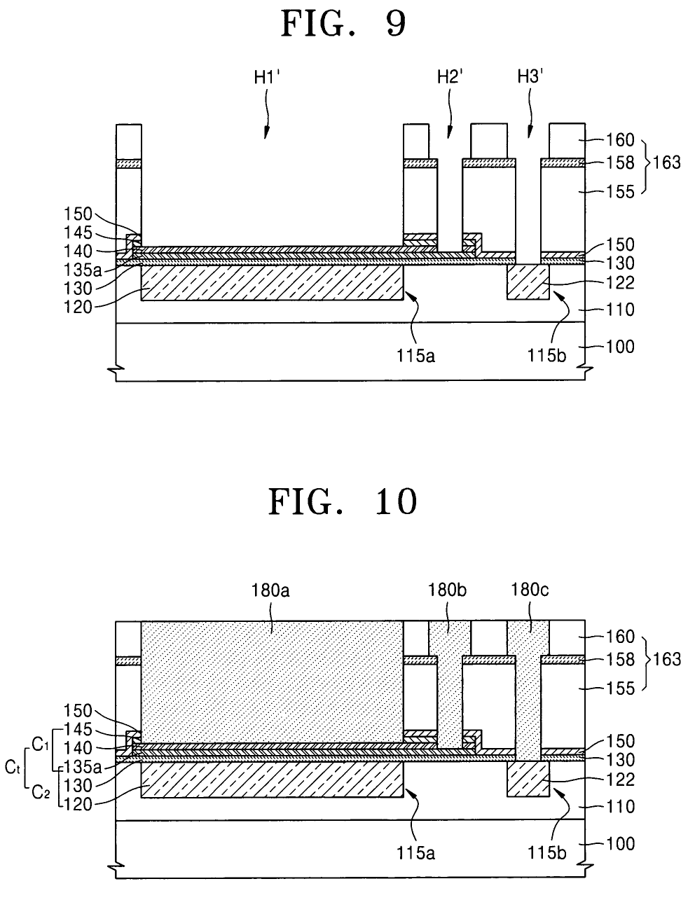

Referring to FIG. 9, the second photoresist pattern 170 may be removed by a well-known method. When enlarging the first and second preliminary via holes H2 and H3, the capping layer 150 and the passivation layer 145 are etched using the etch stopper 158 as a mask. Subsequently, using the inter-metal insulating layer 163, preferably the first insulating layer 155, as a mask, the exposed capping layer 150, the passivation layer 145, and the second insulating layer 140 are etched to form an upper electrode region H1′ and first and second via holes H2′ and H3. More specifically, the exposed capping layer 150 and the passivation layer 145 are etched in the upper electrode region H1′ using the first insulating layer 155 as a mask, thereby exposing the second dielectric film 140. The exposed second dielectric layer 140 is etched in the regions of the first and second via holes H2′ and H3′, so that the intermediary electrode 135a and the first metal interconnect 122, respectively, are exposed.

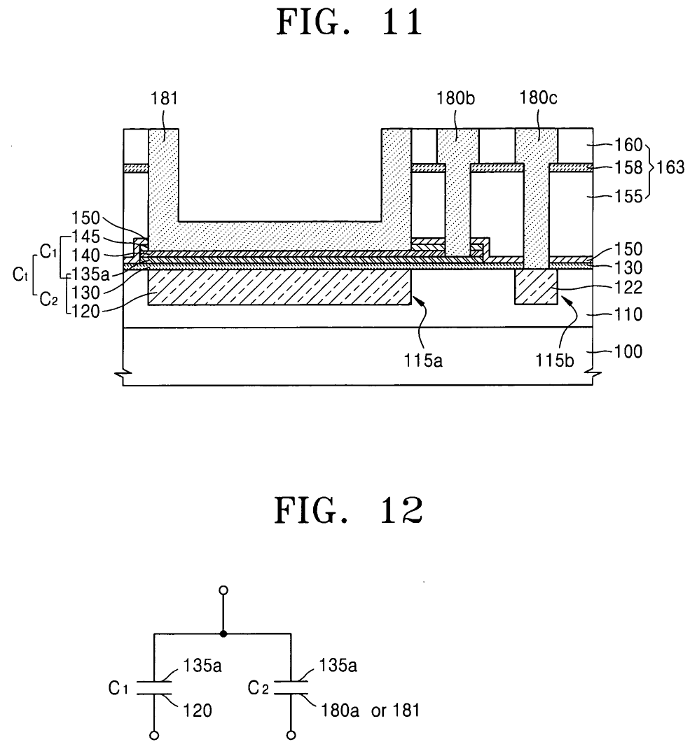

Referring to FIG. 10, a third metal layer is deposited to fill the upper electrode region H1′ and the first and second via holes H2′ and H3′. The third metal layer is then planarized, e.g., using CMP, to expose the surface of the second insulating layer 160, thereby forming a capacitor upper electrode 180a and first and second contact plugs 180b and 180c. The third metal layer may be composed of, e.g., Cu, Al or W. The first plug 180b is an interconnect path for transferring signals to the intermediary electrode 135a. The second plug 180c is a path for connecting the metal interconnect 122 to a metal interconnect (not shown) that will be formed thereon.

FIG. 11 illustrates a sectional view of a MIM capacitor according to an alternative embodiment of the present invention.

In one embodiment of the present invention, as shown in FIG. 10, the third metal layer may be deposited to a thickness sufficient to fill the upper electrode region H1′. Alternatively, in another embodiment of the present invention as shown in FIG. 11, the third metal layer may be deposited to fill the first and second via holes H2′ and H3′ and only partially fill the upper electrode region H1′. When the third metal layer is deposited to fill only the first and second via holes H2′ and H3′, the third metal layer does not fill the relatively wide upper electrode region H1′ but is deposited over a surface of the upper electrode region H1′ to a predetermined thickness. Then, CMP is performed, and an upper electrode 181 is cylindrically formed as shown in FIG. 11.

FIG. 12 illustrates an equivalent circuit diagram of a MIM capacitor according to the present invention.

Referring to FIGS. 10, 11 and 12, a capacitor Cₜ according to the present invention has a structure of stacking a first capacitor C₁ that is composed of the lower electrode 120, the first dielectric film 130 and the intermediary electrode 135a, and a second capacitor C₂ that is composed of the intermediary electrode 135a, the second dielectric film 140 and the upper electrode 180a or 181. When expressed as an equivalent circuit, as shown in FIG. 12, it may be seen that the first and second capacitors C₁ and C₂ are connected in parallel. As is well known, parallel-connected capacitors have a larger capacitance than a serially connected capacitor. Consequently, a capacitor having a large capacitance can be obtained without increasing an area or causing a leakage current.

In the present invention, two parallel-connected capacitors can be formed using a conventional via hole mask and via hole enlargement mask without requiring performance of additional photolithography.

As described above, without performing additional photolithography or decreasing a thickness of a dielectric film, two parallel-connected capacitors may be formed within a restricted area. Accordingly, a capacitor having a large capacitance can be obtained without causing a leakage current.

Moreover, additional photolithography, i.e., a mask process, is not required, thus the difficulty of the overall process is not increased.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A method of manufacturing a metal-insulator-metal (MIM) capacitor, comprising:
forming a lower electrode on a semiconductor substrate;
sequentially forming a first dielectric film, an intermediary electrode, and a second dielectric film on an upper surface of the lower electrode;
forming an inter-metal insulating layer on an upper surface of the second dielectric film;
etching predetermined portions of the inter-metal insulating layer to form an upper electrode region and via hole regions;
selectively etching the second dielectric film exposed in a portion of the via hole regions to expose the intermediary electrode; and
forming a metal layer on the upper electrode region and the via hole regions, thereby forming an upper electrode and contact plugs.

2. The method of manufacturing a MIM capacitor as claimed in claim 1, wherein forming the lower electrode comprises:
forming an interlayer insulating layer on the semiconductor substrate; and
forming the lower electrode within the interlayer insulating layer, wherein a surface of the lower electrode is externally exposed.

3. The method of manufacturing a MIM capacitor as claimed in claim 2, wherein the lower electrode is composed of copper (Cu), aluminum (Al) or tungsten (W).

4. The method of manufacturing a MIM capacitor as claimed in claim 2, wherein sequentially forming the first dielectric film, the intermediary electrode and the second dielectric film comprises:
sequentially stacking the first dielectric film, a metal layer, and the second dielectric film on an upper surface of the interlayer insulating layer; and
patterning the second dielectric film and the metal layer, each of the patterned second dielectric film and metal layer having a length longer than the lower electrode by as much as a predetermined length, the patterned second dielectric film and metal layer overlapping the lower electrode.

5. The method of manufacturing a MIM capacitor as claimed in claim 1, further comprising enlarging entrances of the via holes by as much as a predetermined width while etching the second dielectric film in the portion of the via hole regions.

6. The method of manufacturing a MIM capacitor as claimed in claim 5, wherein etching the second dielectric film on the via hole regions comprises:
forming a photoresist pattern exposing the inter-metal insulating layer on both sides of the via holes;
etching an upper region of the exposed inter-metal insulating layer to a predetermined depth; and
etching the exposed second dielectric film.

7. A method of manufacturing a metal-insulator-metal (MIM) capacitor, comprising:
forming an interlayer insulating layer on an upper surface of a semiconductor substrate, the interlayer insulating layer having a lower electrode and a metal interconnect;
sequentially depositing a first dielectric film, a metal layer for an intermediary electrode, a second dielectric film, and a passivation layer on an upper portion of the interlayer insulating layer;
etching predetermined portions of the passivation layer, the second dielectric film, and the metal layer for the intermediary electrode, the etched passivation layer, second dielectric film, and metal layer overlapping the lower electrode;
forming a capping layer on the passivation layer and the first dielectric film;
forming an inter-metal insulating layer on an upper surface of the capping layer, the inter-metal insulating layer including a first insulating layer, an etch stopper, and a second insulating layer;
etching a predetermined portion of the inter-metal insulating layer to form a preliminary upper electrode region, a first preliminary via hole and a second preliminary via hole;
enlarging entrances of the first and second preliminary via holes;
selectively etching the capping layer, the passivation layer, the second dielectric film and the first dielectric film to expose the second dielectric film in the preliminary upper electrode region, to expose the intermediary electrode in the first preliminary via hole, and to expose the metal interconnect in the second preliminary via hole, thereby defining an upper electrode region, a first via hole and a second via hole, respectively; and
forming a metal layer on the upper electrode region and the first and second via holes, thereby forming an upper electrode and first and second contact plugs.

8. The method of manufacturing a MIM capacitor as claimed in claim 7, wherein forming the interlayer insulating layer having the lower electrode and the metal interconnect comprises:
depositing the interlayer insulating layer on an upper portion of the semiconductor substrate;
etching predetermined portions of the interlayer insulating layer to a predetermined depth to form first and second grooves;
depositing a metal layer filling the first and second grooves; and
planarizing the metal layer to expose the interlayer insulating layer, thereby forming the lower electrode and the metal interconnect.

9. The method of manufacturing a MIM capacitor as claimed in claim 8, wherein the metal layer for forming the lower electrode and the metal interconnect is composed of copper (Cu), aluminum (Al) or tungsten (W).

10. The method of manufacturing a MIM capacitor as claimed in claim 7, wherein the first and second dielectric films are composed of a silicon nitride layer.

11. The method of manufacturing a MIM capacitor as claimed in claim 7, wherein the metal layer for the intermediary electrode is composed of a titanium nitride (TiN) layer or tantalum nitride (TaN) layer.

12. The method of manufacturing a MIM capacitor as claimed in claim 7, wherein the passivation layer is composed of a silicon oxide layer.

13. The method of manufacturing a MIM capacitor as claimed in claim 7, wherein etching the passivation layer, the second dielectric film and the metal layer for the intermediary electrode comprises etching portions of the passivation layer, the second dielectric film and the metal layer, wherein the etched passivation layer, second dielectric film and metal layer overlap the lower electrode and a predetermined portion of the metal layer for the intermediary electrode extends beyond the lower electrode.

14. The method of manufacturing a MIM capacitor as claimed in claim 7, wherein the capping layer is composed of a silicon nitride layer.

15. The method of manufacturing a MIM capacitor as claimed in claim 7, wherein forming the preliminary upper electrode region and the first and second preliminary via hole regions comprises:
forming a first photoresist pattern to expose an area including the lower electrode on the inter-metal insulating layer, an area including the intermediary electrode extending beyond the lower electrode, and an area including the metal interconnect;
etching the inter-metal insulating layer in the form of the first photoresist pattern to expose the capping layer; and
removing the first photoresist pattern.

16. The method of manufacturing a MIM capacitor as claimed in claim 15, wherein enlarging the entrances of the first and second preliminary via holes comprises:
forming a second photoresist pattern on both sides of the first and second preliminary via holes, the second photoresist pattern exposing predetermined portions of the inter-metal insulating layer and covering the preliminary upper electrode region;
etching the second insulating layer of the inter-metal insulating layer in the form of the second photoresist pattern;
removing the second photoresist pattern; and
etching the exposed capping layer and the passivation layer using the etch stopper as a mask.

17. The method of manufacturing a MIM capacitor as claimed in claim 7, wherein forming the upper electrode and the contact plugs comprises:
forming a metal layer filling the upper electrode region; and
planarizing the metal layer to expose a surface of the inter-metal insulating layer.

18. The method of manufacturing a MIM capacitor as claimed in claim 7, wherein forming the upper electrode and the contact plugs comprises:
forming a metal layer filling the first and second via holes; and
planarizing the metal layer to expose a surface of the inter-metal insulating layer.

19. A metal-insulator-metal (MIM) capacitor, comprising:
a semiconductor substrate;
an interlayer insulating layer on an upper surface of the semiconductor substrate, the interlayer insulating layer including a lower electrode and a metal interconnect;
a first dielectric film formed on the interlayer insulating layer;
an intermediary electrode formed on the first dielectric layer and overlapping the lower electrode;
a second dielectric film formed on an upper surface of the intermediary electrode;
an upper electrode formed on an upper surface of the second dielectric film; and
a first contact plug on the intermediary electrode for transferring signals to the intermediary electrode.

20. The MIM capacitor as claimed in claim 19, further comprising a second contact plug on the metal interconnect.

21. The MIM capacitor as claimed in claim 19, wherein the lower electrode and the metal interconnect are buried in an upper portion of the interlayer insulating layer and surfaces of the lower electrode and the metal interconnect are exposed.

22. The MIM capacitor as claimed in claim 19, wherein a first portion of the intermediary electrode overlaps the lower electrode and a second portion of the intermediary electrode extends beyond the lower electrode, and wherein the first contact plug is formed on the second portion of the intermediary electrode extending beyond the lower electrode.

23. The MIM capacitor as claimed in claim 19, further comprising an inter-metal insulating layer on an upper surface of the second dielectric film, wherein the upper electrode and the first contact plug are formed within the inter-metal insulating layer.

24. The MIM capacitor as claimed in claim 23, wherein the upper electrode is buried in a predetermined portion of the inter-metal insulating layer.

25. The MIM capacitor as claimed in claim 23, wherein the upper electrode has a cylindrical-shape and is formed within the inter-metal insulating layer.
